(19) United States
(12) Patent Application Publication
(10) Pub. No.: US 2026/0271425 A1
(43) Pub. Date: Sep. 10, 2026

(54) HORIZONTAL PHOTODIODE AND MANUFACTURING METHOD THEREOF

(71) Applicant: Taiwan-Asia Semiconductor Corporation, Hsinchu City (TW)

(72) Inventor: Ching-Pu Tai, Hsinchu City (TW)

(21) Appl. No.: 19/279,197

(22) Filed: Jul. 24, 2025

(30) Foreign Application Priority Data
Mar. 10, 2025 (TW) 114108818

(51) Int. Cl. H10F 77/14; H10F 30/221; H10F 71/00; H10F 77/124; H10F 77/30; H10F 77/40

(52) U.S. Cl. CPC H10F 77/147; H10F 30/2215; H10F 71/127; H10F 77/1243; H10F 77/334; H10F 77/337; H10F 77/413

(57) ABSTRACT

A horizontal photodiode and a manufacturing method thereof are provided. The horizontal photodiode includes a mesa epitaxial layer, a second conductive type epitaxial layer, a transparent substrate, and an optical bonding layer. The mesa epitaxial layer has a laser-sintered sidewall disposed on the outer periphery of the mesa epitaxial layer. The second conductive type epitaxial layer is disposed under the mesa epitaxial layer. The optical bonding layer is interposed between the transparent substrate and the second conductive type epitaxial layer to block external light from entering the second conductive type epitaxial layer through the transparent substrate.

### CROSS-REFERENCES TO RELATED APPLICATIONS

This application claims the benefit of priority to Taiwanese Patent Application No. 114108818 filed on Mar. 10, 2025, which is hereby incorporated by reference in its entirety.

### BACKGROUND OF THE INVENTION

### FIELD OF THE INVENTION

This invention relates to a horizontal photodiode and a manufacturing method thereof, and in particular to a horizontal photodiode with high structural strength and high signal-to-noise ratio and a manufacturing method thereof.

### Descriptions of the Related Art

A photodiode is an electronic device that converts external optical signals into electrical signals. Its core function is to absorb external light for enabling the detection of optical signals and converting them into measurable current. This conversion is critical for various applications, such as optical communication, optical measurement, and image generation.

The mechanism by which a photodiode absorbs external light relies on the semiconductor material (e.g., silicon substrate) within the diode absorbing light. When photons enter the photodiode and are absorbed, their energy can excite electrons from the valence band to the conduction band for generating electron-hole pairs. These photogenerated carriers are separated under the influence of the built-in electric field within the diode and an electric current is generated.

However, conventional photodiodes face two primary issues. First, short-wave infrared (SWIR) photodiodes, operating in the spectral range of 0.9 to 1.7 micrometers, typically have a material structure grown layer-by-layer on indium phosphide (InP) substrates. However, InP substrates are highly fragile, making them prone to breakage during wafer fabrication, which adversely affects yield and keeps manufacturing costs high, failing to meet the requirements for cost-effective mass production. Second, in practical applications, external light can easily enter the device through exposed sidewalls, causing interference with internal photoelectric effects. This interference compromises the accuracy of the photosensitive region, leading to computational errors in back-end applications of related devices. To address these issues, there is an urgent need in the industry for an innovative photodiode architecture that not only improves the structural strength of the photodiode wafer but also mitigates the low signal-to-noise ratio caused by external noise interference.

### SUMMARY OF THE INVENTION

The primary objective of this invention is to provide an innovative horizontal photodiode and a manufacturing method thereof. Compared to conventional photodiodes, the photodiode of this invention employs wafer transfer and bonding techniques to transfer the epitaxial structure of the photodiode from a fragile epitaxial growth substrate to a high-strength transparent substrate, enhancing the structural strength of the device body, improving process yield, and reducing production costs to meet the requirements for cost-effective production. In particular, this invention utilizes laser sintering technology to form laser-sintered sidewalls within the device structure, effectively blocking external light interference from the device sidewalls, suppressing noise interference, and improving the signal-to-noise ratio (SNR) and photocurrent gain of the device.

To achieve the above objective, this invention provides a horizontal photodiode comprising a mesa epitaxial layer, a second conductive type epitaxial layer, a transparent substrate, and an optical bonding layer. The mesa epitaxial layer includes an intrinsic epitaxial layer, a first conductive type in-situ doped epitaxial layer, and a laser-sintered sidewall. The first conductive type in-situ doped epitaxial layer is disposed on the intrinsic epitaxial layer, and the laser-sintered sidewall is disposed on an outer periphery of the first conductive type in-situ doped epitaxial layer to substantially block external light from entering the first conductive type in-situ doped epitaxial layer through the laser-sintered sidewall. The mesa epitaxial layer is disposed on the second conductive type epitaxial layer, and the optical bonding layer is interposed between the transparent substrate and the second conductive type epitaxial layer to block external light from entering the second conductive type epitaxial layer through the transparent substrate.

In one embodiment of the horizontal photodiode of this invention, the laser-sintered sidewall is further disposed in the intrinsic epitaxial layer.

In one embodiment of the horizontal photodiode of this invention, the first conductive type in-situ doped epitaxial layer is an N-type in-situ doped indium phosphide (InP) epitaxial layer, doped with one of sulfur (S) or silicon (Si), with a doping concentration of 10¹⁷ to 10¹⁹ cm⁻³.

In one embodiment of the horizontal photodiode of this invention, the optical bonding layer is a distributed Bragg reflector (DBR) layer.

In one embodiment of the horizontal photodiode of this invention, the transparent substrate further includes a passivation layer for bonding with the optical bonding layer.

In one embodiment of the horizontal photodiode of this invention, the passivation layer is selected from the group consisting of silicon oxide, titanium oxide, and combinations thereof.

In one embodiment of the horizontal photodiode of this invention, the horizontal photodiode further includes an optical layer, the optical layer being a multi-channel band-pass filter (MBPF) layer covering a surface and a sidewall of the mesa epitaxial layer, configured to allow light of a specific wavelength band from external light to pass through while blocking other light outside the specific wavelength band.

In one embodiment of the horizontal photodiode of this invention, the optical layer further includes an anti-reflection (AR) layer to reduce surface reflection loss of the optical layer.

In one embodiment of the horizontal photodiode of this invention, the horizontal photodiode further includes a first metal ring disposed on the surface of the first conductive type in-situ doped epitaxial layer inside the laser-sintered sidewall and partially covered by the optical layer.

In one embodiment of the horizontal photodiode of this invention, the horizontal photodiode further includes a second metal ring disposed adjacent to the sidewall of the mesa epitaxial layer and electrically connected to the second conductive type epitaxial layer.

To achieve the above objective, this invention provides a manufacturing method for a horizontal photodiode, comprising the following steps. First, provide an epitaxial growth substrate and sequentially grow a first conductive type in-situ doped epitaxial layer, an intrinsic epitaxial layer, and a second conductive type epitaxial layer on the epitaxial growth substrate. Second, provide an optical bonding layer on the second conductive type epitaxial layer. Third, bond a transparent substrate to the optical bonding layer and remove the epitaxial growth substrate. Fourth, provide a laser-sintered sidewall disposed on an outer periphery of the first conductive type in-situ doped epitaxial layer. Fifth, remove portions of the first conductive type in-situ doped epitaxial layer and the intrinsic epitaxial layer to form a mesa epitaxial layer. Finally, provide an optical layer covering a surface and a sidewall of the mesa epitaxial layer.

In one embodiment of the manufacturing method for the horizontal photodiode of this invention, the step of providing a laser-sintered sidewall is to provide a laser to form the laser-sintered sidewall, disposed on the outer periphery of the first conductive type in-situ doped epitaxial layer and in the intrinsic epitaxial layer.

In one embodiment of the manufacturing method for the horizontal photodiode of this invention, the step of providing a first conductive type in-situ doped epitaxial layer is to provide an N-type in-situ doped indium phosphide (InP) epitaxial layer.

In one embodiment of the manufacturing method for the horizontal photodiode of this invention, the step of providing an N-type in-situ doped indium phosphide (InP) epitaxial layer is to perform indium phosphide (InP) epitaxy using metal-organic chemical vapor deposition (MOCVD) while simultaneously doping with one of sulfur (S) or silicon (Si), with a doping concentration of 10¹⁷ to 10¹⁹ cm⁻³.

In one embodiment of the manufacturing method for the horizontal photodiode of this invention, the step of providing an optical bonding layer is to provide a distributed Bragg reflector layer.

In one embodiment of the manufacturing method for the horizontal photodiode of this invention, the method further includes a step of providing a first metal ring after the step of providing a laser-sintered sidewall, wherein the first metal ring is disposed on the surface of the first conductive type in-situ doped epitaxial layer inside the laser-sintered sidewall.

In one embodiment of the manufacturing method for the horizontal photodiode of this invention, the method further includes providing a second metal ring disposed adjacent to the sidewall of the mesa epitaxial layer and electrically connected to the second conductive type epitaxial layer.

In one embodiment of the manufacturing method for the horizontal photodiode of this invention, the step of providing an optical layer is to provide a multi-channel band-pass filter layer configured to allow light of a specific wavelength band from external light to pass through while blocking other light outside the specific wavelength band.

In one embodiment of the manufacturing method for the horizontal photodiode of this invention, the step of providing an optical layer further includes a step of providing an anti-reflection layer to reduce surface reflection loss of the optical layer.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 to FIG. 9 are cross-sectional schematic diagrams illustrating the manufacturing of a horizontal photodiode in one embodiment of this invention; and

FIG. 10 is a schematic diagram illustrating the process steps of a horizontal photodiode in one embodiment of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

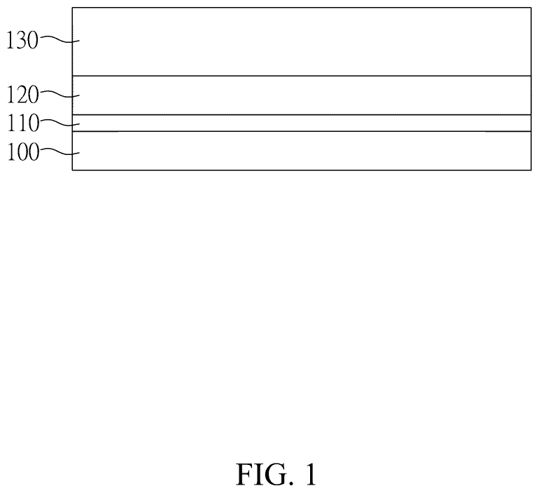

Please refer to FIG. 1 to FIG. 9 together, which illustrate cross-sectional schematic diagrams of the manufacturing of a horizontal photodiode in one embodiment of this invention. In particular, this horizontal photodiode is a compound semiconductor horizontal photodiode. In this embodiment, the manufacturing of the horizontal photodiode 10 begins by epitaxially growing an ohmic contact epitaxial layer 110 on an epitaxial growth substrate 100, which serves to form an ohmic contact with a metal layer in subsequent metal interconnection processes. Specifically, the epitaxial growth substrate 100 may be, but is not limited to, an indium phosphide (InP) substrate. The ohmic contact epitaxial layer 110 may be, but is not limited to, an indium gallium arsenide (InGaAs) epitaxial layer.

Next, a first conductive type in-situ doped epitaxial layer 120 and an intrinsic epitaxial layer 130 are sequentially grown epitaxially on the ohmic contact epitaxial layer 110, as shown in FIG. 1. Specifically, the first conductive type in-situ doped epitaxial layer 120 is an N-type doped epitaxial layer formed by using metal-organic chemical vapor deposition (MOCVD). For example, during the epitaxial growth of an indium phosphide (InP) epitaxial layer, doping is performed simultaneously with, but not limited to, one of sulfur (S) or silicon (Si) as the dopant, with a doping concentration of approximately 10¹⁷ to 10¹⁹ cm⁻³, to establish an appropriate built-in electric field to drive electron drift. Additionally, the intrinsic epitaxial layer 130 may be an indium gallium arsenide (InGaAs) epitaxial layer disposed on the first conductive type in-situ doped epitaxial layer 120, with a low doping concentration of approximately 10¹⁴ to 10¹⁵ cm⁻³, ensuring a long carrier drift distance, preventing carrier recombination within the intrinsic epitaxial layer, and effectively facilitating electron-hole separation and drift to improve photoresponse efficiency. It should be noted that, due to the uniform doping distribution formed by the “in-situ doping” process in the first conductive type in-situ doped epitaxial layer 120 of this invention, compared to doping distributions formed by conventional ion implantation and diffusion processes, the ion doping distribution in the first conductive type in-situ doped epitaxial layer 120 is uniform, thereby enhancing the photoresponse efficiency and current gain of the photodiode.

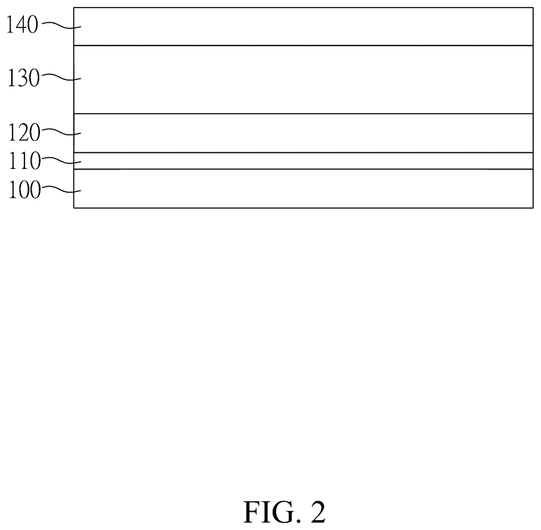

Please refer to FIG. 2, where a second conductive type epitaxial layer 140 is subsequently grown epitaxially on the intrinsic epitaxial layer 130. Specifically, the second conductive type epitaxial layer 140 may be, but is not limited to, a P-type indium phosphide (InP) epitaxial layer. This P-type indium phosphide epitaxial layer may be formed by using conventional ion implantation and diffusion processes or, similar to the above, using an in-situ doping process with one of zinc (Zn), magnesium (Mg), or beryllium (Be) as the dopant, with a doping concentration of 10¹⁷ to 10¹⁹ cm⁻³.

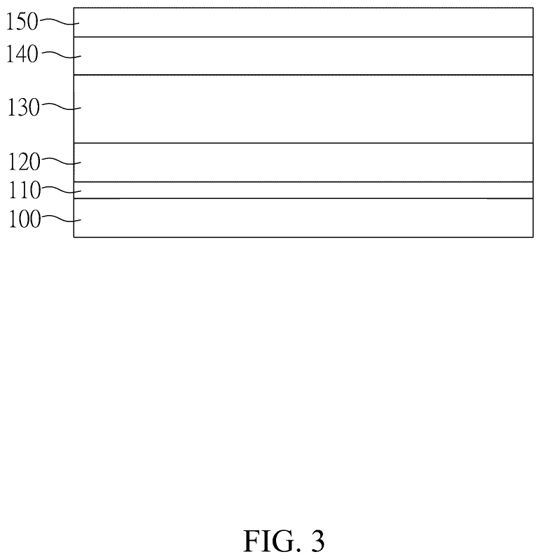

Next, an optical bonding layer 150 is grown on the second conductive type epitaxial layer 140, as shown in FIG. 3, for subsequent wafer transfer and bonding. In particular, this optical bonding layer 150 may also serve as an optical reflective layer, such as, but not limited to, a distributed Bragg reflector (DBR) layer. This DBR layer is constructed by using alternating stacks of high-and low-refractive-index materials, such as silicon oxide and titanium oxide, forming a reflective film. Due to interference effects at the interfaces of the multilayer structure, light of specific wavelengths is strongly reflected. Therefore, the reason for using a DBR film as the optical bonding layer 150 in this invention is to leverage its optical reflection properties to effectively isolate noise from the bottom of the device and enhance the responsiveness of the photodiode.

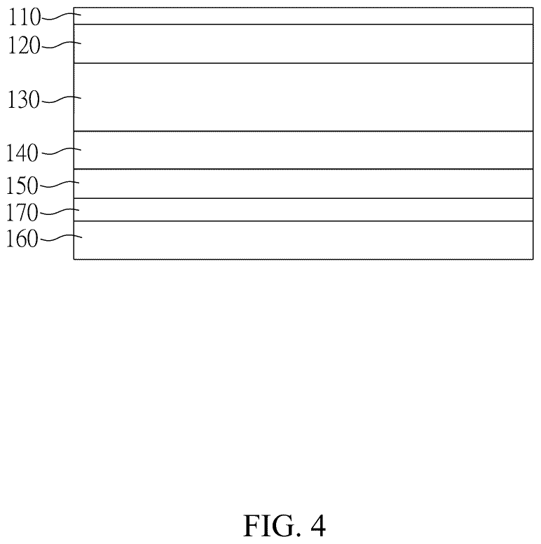

Next, as shown in FIG. 4, a transparent substrate 160 is provided, which may be, but is not limited to, a sapphire substrate. The transparent substrate 160 includes a passivation layer 170, specifically selected from the group consisting of silicon oxide, titanium oxide, and combinations thereof, to facilitate wafer transfer and bonding between the epitaxial growth substrate 100 and the transparent substrate 160 in conjunction with the optical bonding layer 150. The passivation layer 170 of the transparent substrate 160 is bonded to the optical bonding layer 150 on the epitaxial growth substrate 100. For example, chemical solutions may be used to treat the surfaces of the optical bonding layer 150 and the passivation layer 170 to form dangling bonds, followed by high-temperature and high-pressure application of van der Waals forces to bond the two wafers together. After the optical bonding layer 150 and the passivation layer 170 are bonded, the indium phosphide epitaxial growth substrate 100 is removed through selective chemical etching, with the etching stopping at the indium gallium arsenide (InGaAs) ohmic contact epitaxial layer 110.

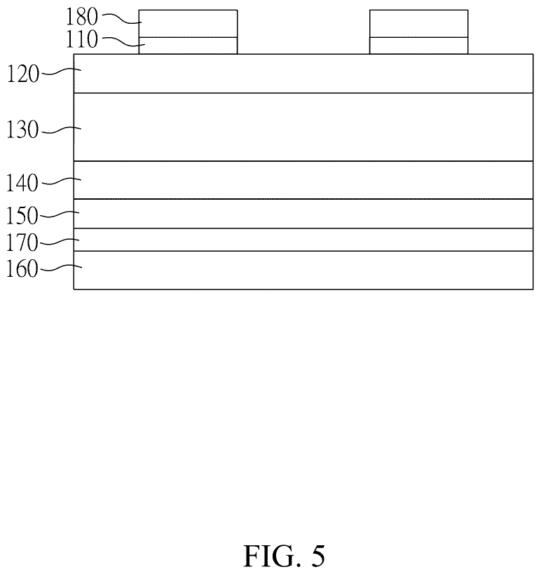

Next, a first conductive type metal layer is formed on the ohmic contact epitaxial layer 110, and a patterning process is used to etch away portions of the first conductive type metal layer and the ohmic contact epitaxial layer 110, forming a first conductive type metal ring 180 and a patterned ohmic contact epitaxial layer 110 beneath it, disposed on the upper surface of the first conductive type in-situ doped epitaxial layer 120, as shown in FIG. 5. Specifically, the first conductive type metal ring 180 is an N-type metal material, which may be, but is not limited to, one of chromium (Cr), palladium (Pd), gold (Au), titanium (Ti), aluminum (Al), silver (Ag), or a combination of their alloys.

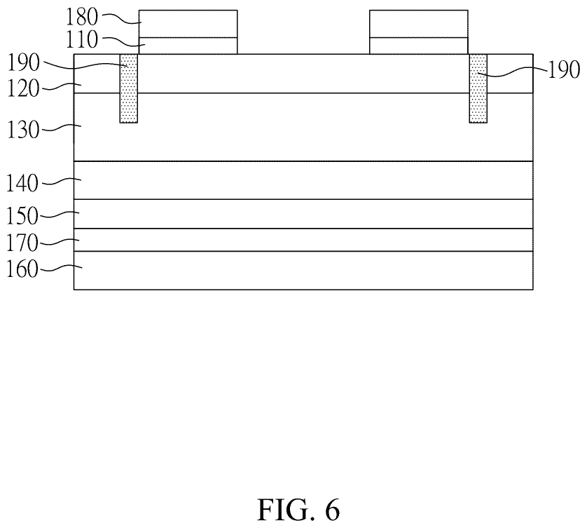

Next, as shown in FIG. 6, to address the issue of low signal-to-noise ratio caused by external light interference, this invention specifically provides a first laser at the outer periphery of the structural body of the horizontal photodiode by using laser sintering to form a first laser-sintered sidewall 190 disposed on the outer periphery of the first conductive type in-situ doped epitaxial layer 120 to define an active region and substantially block external light from entering the first conductive type in-situ doped epitaxial layer 120. In particular, the first laser-sintered sidewall 190 is disposed inside the device sidewall, with the first conductive type metal ring 180 disposed on the inner upper edge of the first laser-sintered sidewall 190, and the first laser-sintered sidewall 190 blocks unintended external light from entering the active region of the device through the device sidewall, preventing subsequent malfunctions. Specifically, a green laser or ultraviolet (UV) laser may be used to form a laser-sintered sidewall with a length of at least 1 micrometer (μm) on the outer periphery of the first conductive type in-situ doped epitaxial layer 120 to substantially block external light from entering the first conductive type in-situ doped epitaxial layer 120. The length of this first laser-sintered sidewall 190 may be adjusted based on the specifications of the horizontal photodiode device. Preferably, the first laser-sintered sidewall 190 may further be disposed in the intrinsic epitaxial layer to ensure that unintended external light does not enter the diode device through the device sidewall, causing noise, while also enhancing the electrostatic protection capability of the horizontal photodiode.

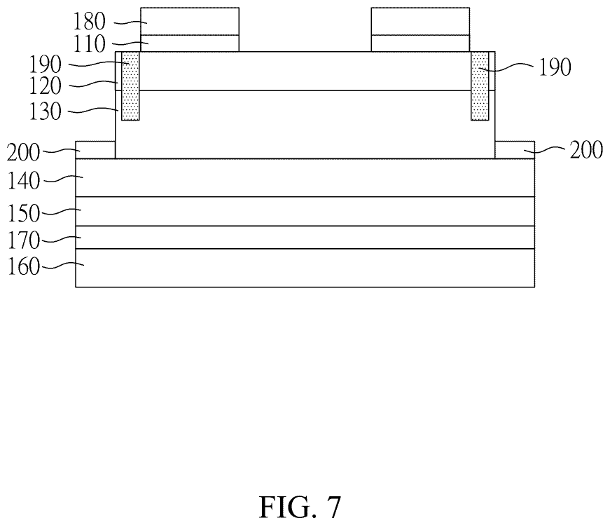

Next, a mesa etching process is performed. Portions of the first conductive type in-situ doped epitaxial layer 120 and the intrinsic epitaxial layer 130 are removed by using dry or wet etching to form a mesa epitaxial layer in the horizontal device structure, as shown in FIG. 7, to expose a portion of the surface of the second conductive type epitaxial layer 140 for use as the second conductive type electrode position. Subsequently, a metal process is performed to form a second conductive type metal ring 200 on the exposed surface of the second conductive type epitaxial layer 140 outside the sidewall of the mesa epitaxial layer, electrically connected to the second conductive type epitaxial layer 140. Specifically, the second conductive type metal ring 200 is a P-type metal material, which may be, but is not limited to, one of platinum (Pt), palladium (Pd), gold (Au), or a combination of their alloys.

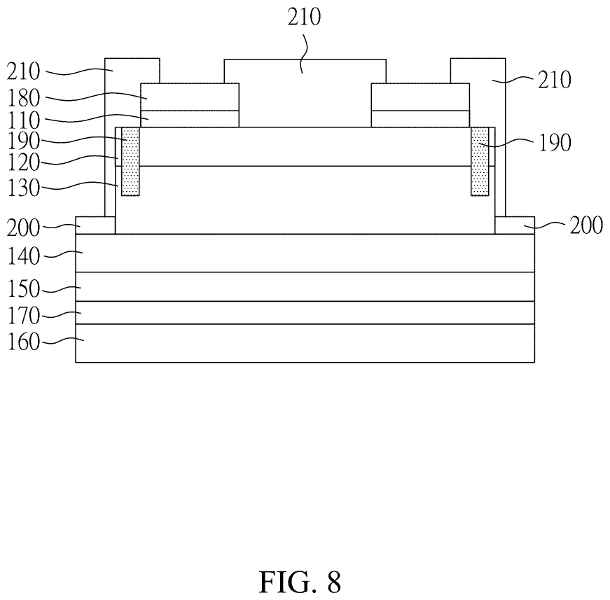

In particular, to control the wavelength range of light entering the photodiode, this invention employs a special optical material instead of a conventional protective layer, providing both electrical isolation and filtering functions. As shown in FIG. 8, an optical layer 210 is formed to cover the surface and sidewalls of the mesa epitaxial layer, partially covering the first conductive type metal ring 180 and the second conductive type metal ring 200, exposing portions of the upper surfaces of the first conductive type metal ring 180 and the second conductive type metal ring 200. Specifically, the optical layer 210 covers only the exposed upper surface of the first conductive type in-situ doped epitaxial layer 120 and the exposed sidewalls of the first conductive type in-situ doped epitaxial layer 120 and the intrinsic epitaxial layer 130, precisely controlling external light of a specific wavelength to enter the mesa epitaxial layer while blocking other light outside the specific wavelength, thereby eliminating unintended external noise interference.

Specifically, in a particular embodiment, the optical layer 210 is a multi-channel band-pass filter (MBPF) layer covering the surface and sidewalls of the mesa epitaxial layer. In practical applications, the composition of the multi-channel band-pass filter layer can be adjusted based on the required filtering wavelength bands, using, for example, but not limited to, dielectric materials such as silicon oxide (SiOₓ), titanium oxide (TiOₓ), or tantalum oxide (Ta₂O₂). In a preferred embodiment, the optical layer 210 further includes an anti-reflection (AR) layer to enhance the transmission of light in the specific wavelength band and reduce surface reflection loss of the optical layer 210.

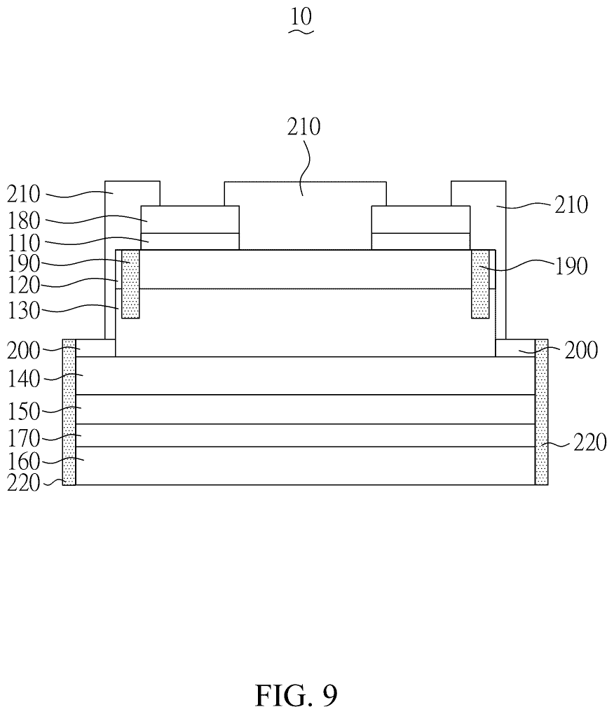

Finally, as shown in FIG. 9, the sapphire substrate is diced to form individual independent horizontal photodiode devices. Specifically, a second laser is provided, using laser cutting to form a second laser-sintered sidewall 220 on the sidewalls of the transparent substrate 160, passivation layer 170, optical bonding layer 150, second conductive type epitaxial layer 140, and second conductive type metal ring 200, thereby forming individual independent horizontal photodiodes 10. Additionally, this second laser-sintered sidewall 220 also serves to block external light from entering the device through the device sidewall, preventing interference.

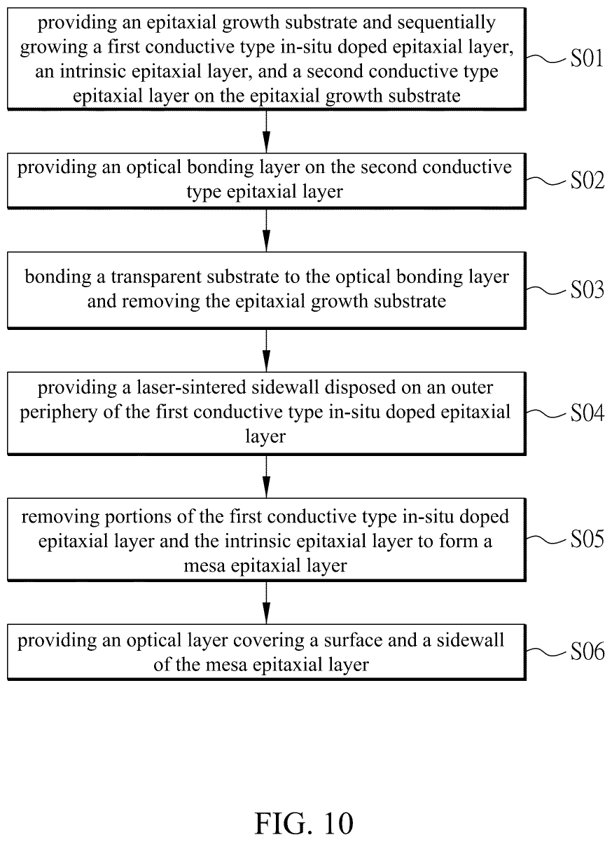

Please refer to FIG. 10, which illustrates a schematic diagram of the process steps for manufacturing the horizontal photodiode of this invention. First, in step S01, an epitaxial growth substrate is provided, and a first conductive type in-situ doped epitaxial layer, an intrinsic epitaxial layer, and a second conductive type epitaxial layer are sequentially grown on the substrate. Next, in step S02, an optical bonding layer is provided on the second conductive type epitaxial layer. In step S03, a transparent substrate is bonded to the optical bonding layer, and the epitaxial growth substrate is removed. In step S04, a laser-sintered sidewall is provided on an outer periphery of the first conductive type in-situ doped epitaxial layer. In step S05, portions of the first conductive type in-situ doped epitaxial layer and the intrinsic epitaxial layer are removed to form a mesa epitaxial layer. Finally, in step S06, an optical layer is provided to cover the surface and sidewalls of the mesa epitaxial layer. The descriptions of the related components can be referred to the above content and will not be repeated here.

As shown in FIG. 9, the horizontal photodiode 10 of this invention utilizes wafer transfer and bonding technology to transfer the main body of the photodiode device to a high-strength sapphire transparent substrate, addressing the fragility issue of indium phosphide substrates used in conventional SWIR photodiodes, enhancing device structural strength, improving process yield, and reducing manufacturing costs to meet the requirements for cost-effective mass production. Furthermore, the horizontal photodiode of this invention incorporates several designs to further block external noise interference, thereby improving the signal-to-noise ratio of the device and enhancing photoresponse efficiency and current gain. For example, the optical bonding layer 150 disposed above the transparent substrate 160 at the bottom of the device has a reflector structure to reflect external light from the bottom of the device, preventing it from entering the device and causing noise interference. Regarding the device sidewalls, this invention provides two laser-sintered sidewalls to prevent noise from entering the active region through the sidewall which includes the first laser-sintered sidewall 190 and the outermost second laser-sintered sidewall 220, both of which effectively block noise interference from the device sidewall. At the top of the device, the multi-channel band-pass filter layer is used to control the passage of light in a specific wavelength band while blocking light in other wavelength bands. Additionally, the anti-reflection layer enhances the transmission of light in the specific wavelength band and reduces reflection loss at the surface of the optical layer. Overall, the horizontal photodiode of this invention features a comprehensive design to mitigate noise interference, significantly improving the signal-to-noise ratio and enhancing photocurrent gain.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. A horizontal photodiode, comprising:
a mesa epitaxial layer having an intrinsic epitaxial layer, a first conductive type in-situ doped epitaxial layer, and a laser-sintered sidewall, wherein the first conductive type in-situ doped epitaxial layer is disposed on the intrinsic epitaxial layer, and the laser-sintered sidewall is disposed on an outer periphery of the first conductive type in-situ doped epitaxial layer to substantially block external light from entering the first conductive type in-situ doped epitaxial layer through the laser-sintered sidewall;
a second conductive type epitaxial layer, wherein the mesa epitaxial layer is disposed on the second conductive type epitaxial layer;
a transparent substrate; and
an optical bonding layer interposed between the transparent substrate and the second conductive type epitaxial layer to block external light from entering the second conductive type epitaxial layer through the transparent substrate.

2. The horizontal photodiode of claim 1, wherein the laser-sintered sidewall is further disposed in the intrinsic epitaxial layer.

3. The horizontal photodiode of claim 1, wherein the first conductive type in-situ doped epitaxial layer is an N-type in-situ doped indium phosphide (InP) epitaxial layer, doped with one of sulfur (S) or silicon (Si), with a doping concentration of 10¹⁷ to 10¹⁹ cm⁻³.

4. The horizontal photodiode of claim 1, wherein the optical bonding layer is a distributed Bragg reflector (DBR) layer.

5. The horizontal photodiode of claim 1, wherein the transparent substrate further includes a passivation layer for bonding with the optical bonding layer.

6. The horizontal photodiode of claim 5, wherein the passivation layer is selected from the group consisting of silicon oxide, titanium oxide, and combinations thereof.

7. The horizontal photodiode of claim 1, further comprising an optical layer, the optical layer being a multi-channel band-pass filter (MBPF) layer covering a surface and a sidewall of the mesa epitaxial layer configured to allow light of a specific wavelength band from external light to pass through while blocking other light outside the specific wavelength band.

8. The horizontal photodiode of claim 7, wherein the optical layer further includes an anti-reflection (AR) layer to reduce surface reflection loss of the optical layer.

9. The horizontal photodiode of claim 7, further comprising a first metal ring disposed on the surface of the first conductive type in-situ doped epitaxial layer inside the laser-sintered sidewall and partially covered by the optical layer.

10. The horizontal photodiode of claim 1, further comprising a second metal ring disposed adjacent to the sidewall of the mesa epitaxial layer and electrically connected to the second conductive type epitaxial layer.

11. A manufacturing method for a horizontal photodiode, comprising:
providing an epitaxial growth substrate and sequentially growing a first conductive type in-situ doped epitaxial layer, an intrinsic epitaxial layer, and a second conductive type epitaxial layer on the epitaxial growth substrate;
providing an optical bonding layer on the second conductive type epitaxial layer;
bonding a transparent substrate to the optical bonding layer and removing the epitaxial growth substrate;
providing a laser-sintered sidewall disposed on an outer periphery of the first conductive type in-situ doped epitaxial layer;
removing portions of the first conductive type in-situ doped epitaxial layer and the intrinsic epitaxial layer to form a mesa epitaxial layer; and
providing an optical layer covering a surface and a sidewall of the mesa epitaxial layer.

12. The manufacturing method for a horizontal photodiode of claim 11, wherein the step of providing a laser-sintered sidewall is to provide a laser to form the laser-sintered sidewall disposed on the outer periphery of the first conductive type in-situ doped epitaxial layer and in the intrinsic epitaxial layer.

13. The manufacturing method for a horizontal photodiode of claim 11, wherein the step of providing a first conductive type in-situ doped epitaxial layer is to provide an N-type in-situ doped indium phosphide (InP) epitaxial layer.

14. The manufacturing method for a horizontal photodiode of claim 13, wherein the step of providing an N-type in-situ doped indium phosphide (InP) epitaxial layer is to perform indium phosphide (InP) epitaxy using metal-organic chemical vapor deposition (MOCVD) while simultaneously doping with one of sulfur (S) or silicon (Si), with a doping concentration of 10¹⁷ to 10¹⁹ cm⁻³.

15. The manufacturing method for a horizontal photodiode of claim 11, wherein the step of providing an optical bonding layer is to provide a distributed Bragg reflector layer.

16. The manufacturing method for a horizontal photodiode of claim 11, further comprising a step of providing a first metal ring after the step of providing a laser-sintered sidewall wherein the first metal ring is disposed on the surface of the first conductive type in-situ doped epitaxial layer inside the laser-sintered sidewall.

17. The manufacturing method for a horizontal photodiode of claim 11, further comprising a step of providing a second metal ring disposed adjacent to the sidewall of the mesa epitaxial layer and electrically connected to the second conductive type epitaxial layer.

18. The manufacturing method for a horizontal photodiode of claim 11, wherein the step of providing an optical layer is to provide a multi-channel band-pass filter layer configured to allow light of a specific wavelength band from external light to pass through while blocking other light outside the specific wavelength band.

19. The manufacturing method for a horizontal photodiode of claim 18, wherein the step of providing an optical layer further comprises step of providing an anti-reflection layer to reduce surface reflection loss of the optical layer.
